(19) United States
(12) Patent Application Publication
(10) Pub. No.: US 2005/0170609 A1
(43) Pub. Date: Aug. 4, 2005

(54) Conductive bond for through-wafer interconnect

(76) Inventors: Susan A. Alie, Stoneham, MA (US); Bruce K. Wachtmann, Concord, MA (US); Lawrence E. Felton, Hopkinton, MA (US); Changhan Yun, Boston, MA (US)

Correspondence Address: Jeffrey T. Klayman;Brombering & Sunstein LLP, 125 Summer Street, Boston, MA, 02110-1618, US

(21) Appl. No.: 11/050,469

(22) Filed: Feb. 3, 2005

Related U.S. Application Data
(63) Continuation-in-part of application No. 10/737,231, filed on Dec. 15, 2003.
(63) Continuation-in-part of application No. 10/827,680, filed on Apr. 19, 2004.
(60) Provisional application No. 60/542,261, filed on Feb. 5, 2004.

(51) Int. Cl. H01L 21/30; H01L 21/46; H01L 23/48; H01L 23/52; H01L 29/40

(52) U.S. Cl. 438/455

(57) ABSTRACT

A conductive bond for through-wafer interconnect is produced by forming an electrode through a first wafer from a component on a front side of the first wafer to a back side of the first wafer, forming a first electrically conductive interface in contact with an exposed portion of the electrode on the back side of the first wafer, and conductively bonding the first electrically conductive interface with a second electrically conductive interface on a second wafer under pressure at a temperature below the thermal budget of the stacked wafer device. The process temperature is generally well below the melting points of the electrically conductive interfaces. In some embodiments, the conductive bonding may be facilitated or enabled by performing the conductive bonding in a vacuum.

### PRIORITY

This patent application is a continuation-in-part of, and thus claims priority from, U.S. patent application Ser. No. 10/737,231 entitled “SEMICONDUCTOR ASSEMBLY WITH CONDUCTIVE RIM AND METHOD OF PRODUCING THE SAME,” which was filed Dec. 15, 2003 in the names of Susan A. Alie, Michael Judy, Bruce K. Wachtmann, and David Kneedler, and is also a continuation-in-part of, and thus claims priority from U.S. patent application Ser. No. 10/827,680 entitled “MEMS DEVICE WITH CONDUCTIVE PATH THROUGH SUBSTRATE,” which was filed Apr. 19, 2004 in the names of Kieran P. Harney, Lawrence E. Felton, Thomas Kieran Nunan, Susan A. Alie, and Bruce K. Wachtmann. This patent application also claims priority from U.S. Provisional Patent Application No. 60/542,261 entitled “CONDUCTIVE BOND FOR THROUGH-WAFER INTERCONNECT,” which was filed Feb. 5, 2004 in the names of Susan A. Alie, Bruce K. Wachtmann, Lawrence E. Felton, and Changhan Yun. The above patent applications are hereby incorporated herein by reference in their entireties.

### FIELD OF THE INVENTION

The invention generally relates to forming electrical interconnections in a stacked die device.

### BACKGROUND OF THE INVENTION

There are a number of scenarios where a stacked die approach is of value. For example, a MEMS die may be conductively connected to a circuit die. Such die may require both electrical and mechanical interconnections. Parasitic capacitance and resistance problems also should be addressed in such situations.

Thus, a stacked die device may include two or more wafers that are bonded to one another. Each wafer may include micromachined components and/or integrated circuit components. Generally speaking, the various components on the wafers are fragile, and many of the components can be damaged by high temperatures. In essence, then, there is a “thermal budget” for the stacked die device that is determined by the most temperature-sensitive feature.

### SUMMARY OF THE INVENTION

Embodiments of the present invention provide for electrically interconnecting wafers in stacked wafer devices within the thermal budgets of the stacked wafer devices. Specifically, an electrode is formed through a first wafer from a component on a front side of the first wafer to a back side of the first wafer. A first electrically conductive interface is formed in contact with an exposed portion of the electrode on the back side of the first wafer. The first electrically conductive interface is conductively bonded with a second electrically conductive interface on a second wafer under pressure at a temperature below the thermal budget of the stacked wafer device. Such a temperature is generally well below the melting point of at least one of the electrically conductive interfaces. Depending on the substances in the first and second electrically conductive interfaces, such conductive bonding can occur by way of interdiffusion, thermocompression, or other mechanism. In some embodiments, the conductive bonding may be facilitated or enabled by performing the conductive bonding in an ambient (e.g., air or other gas) or in a vacuum. The conductive bonding produces an electrically conductive interconnection between the wafers, and, more particularly, from the component on the front side of the first wafer to the second electrically conductive interface on the second wafer, without damaging features on either wafer. This electrical connection allows the wafers to operate as one integrated device.

In accordance with one aspect of the invention there is provided a method for electrically interconnecting wafer devices. The method involves forming an electrode through a first wafer from a component on a front side of the first wafer to a back side of the first wafer; forming a first electrically conductive interface in contact with an exposed portion of the electrode on the back side of the first wafer; and conductively bonding the first electrically conductive interface with a second electrically conductive interface on a second wafer under pressure at a temperature below the melting point of at least one of the electrically conductive interfaces.

The first and second interfaces may include gold (Au). The first and second interfaces may include aluminum-copper (AlCu). The first and second interfaces may include platinum (Pt) with or without an adhesive underlayer. One of the interfaces may include silicon (Si) and the other may include platinum (Pt) (with or without an adhesive underlayer). One of the interfaces may include doped polysilicon and the other may include a solderable metal.

In certain embodiments of the invention, the conductive bonding is performed in a vacuum. The conductive bond may be formed through interdiffusion, thermocompression, or other mechanism. The electrode may be formed by filling a lined through-wafer via in the first wafer with an electrically conductive material. The first wafer may be a MEMS wafer, and the second wafer may be an integrated circuit wafer.

In accordance with another aspect of the invention there is provided an apparatus comprising a first wafer having (1) an electrode passing through the first wafer from a component on a top side to a bottom side, and (2) a first electrically conductive interface on the bottom side of the first wafer in contact with an exposed portion of the electrode; and a second wafer having a second electrically conductive interface conductively bonded with the first electrically conductive interface under pressure at a temperature below the melting point of at least one of the electrically conductive interfaces.

The first and second interfaces may include gold (Au). The first and second interfaces may include aluminum-copper (AlCu). The first and second interfaces may include platinum (Pt) with or without an adhesive underlayer. One of the interfaces may include silicon (Si) and the other may include platinum (Pt) (with or without an adhesive underlayer). One of the interfaces may include doped polysilicon and the other may include a solderable metal.

The conductive bond may be formed through interdiffusion, thermocompression, or other mechanism. The first wafer may be a MEMS wafer, and the second wafer may be an integrated circuit wafer.

### BRIEF DESCRIPTION OF THE DRAWINGS

The foregoing and advantages of the invention will be appreciated more fully from the following further description thereof with reference to the accompanying drawings wherein:

FIGS. 1A-1D show one example of a stacked die device in accordance with an embodiment of the present invention;

FIGS. 2A-2D show another example of a stacked die device in accordance with an embodiment of the present invention;

FIGS. 3A-3D show another example of a stacked die device in accordance with an embodiment of the present invention; and

FIG. 4 is a logic flow diagram for conductively bonding wafers in accordance with an embodiment of the present invention.

### DESCRIPTION OF ILLUSTRATIVE EMBODIMENTS

Embodiments of the present invention provide for electrically interconnecting wafers in stacked wafer devices within the thermal budgets of the stacked wafer devices. Specifically, an electrode is formed through a first wafer from a component on a front side of the first wafer to a back side of the first wafer. A first electrically conductive interface is formed in contact with an exposed portion of the electrode on the back side of the first wafer. The first electrically conductive interface is typically a raised structure that protrudes from the back side of the first wafer. The first electrically conductive interface is conductively bonded with a second electrically conductive interface on a second wafer under pressure at a temperature below the thermal budget of the stacked wafer device. The process temperature is generally well below the melting point of at least one of the electrically conductive interfaces. Depending on the substances in the first and second electrically conductive interfaces, such conductive bonding can occur by way of interdiffusion, thermocompression, or other mechanism. In some embodiments, the conductive bonding may be facilitated or enabled by performing the conductive bonding in an ambient (e.g., air or other gas) or in a vacuum. The conductive bonding produces an electrically conductive interconnection between the wafers, and, more particularly, from the component on the front side of the first wafer to the second electrically conductive interface on the second wafer, without damaging features on either wafer. This electrical connection allows the wafers to operate as one integrated device.

In a typical embodiment of the present invention, the first wafer includes an opening (referred to hereinafter as a “through-wafer via”). The through-wafer via is typically lined with one or more insulating materials. The electrode passes through the through-wafer via. The electrode may be formed by filling the through-wafer via with an electrically conductive material, such as silicon, polysilicon, or metal. The insulating lining, if present, electrically isolates the electrode from the wafer.

The temperature and other parameters selected for a particular embodiment of the invention may depend on a number of factors, including, but not limited to, the materials in the electrically conductive interfaces, the amount of pressure applied, the size of the features in contact, and whether the conductive bonding is performed in an ambient (e.g., air or another gas) or in a vacuum. Typically, conductive bonding is performed within the temperature range of about 280 C to 500 C. Generally speaking, increasing bond pressure and/or decreasing the size of the features in contact and/or using a vacuum during bonding could improve conductive bonding.

In embodiments of invention in which a metal, such as platinum, gold, or aluminum-copper (AlCu), is deposited as an electrically conductive interface onto a silicon or polysilicon electrode, it may be advantageous to process the exposed portion of the electrode prior to deposition of the metal, for example, by sputter etching, in order to facilitate adhesion and electrical connectivity. Alternatively, or additionally, an adhesion material, such as titanium-tungsten or titanium, may be deposited as an underlayer.

In a first exemplary embodiment, Wafer 1 has a lined through-wafer via filled with doped polysilicon. Platinum is deposited and patterned onto the exposed polysilicon in the via on the backside of the wafer. Wafer 2 has a conductive polysilicon interconnect. The platinum of Wafer 1 is brought into contact with the polysilicon interconnect on Wafer 2 and heated above about 280 C but below about 450 C. The two wafers are conductively bonded through the formation of platinum-silicide at the platinum-polysilicon interface on both wafers.

In a second exemplary embodiment, Wafer 1 has a lined through-wafer via filled with doped polysilicon. A solderable metal, such as platinum or gold, is deposited and patterned onto the exposed polysilicon in the via on the backside of the wafer. Wafer 2 has solder bumps on the interconnect bond pads. Wafer 1 and Wafer 2 are conductively bonded by aligning the solderable metal on Wafer 1 to the solder bumps on wafer 2 and applying pressure and temperature less than about 450 C.

In a third exemplary embodiment, Wafer 1 has a lined through-wafer via filled with metal. Metal is deposited and patterned onto the exposed metal in the via on the backside of the wafer, forming conductive pads on the metal filled vias. The metal pads on Wafer 1 are aligned to metal bond pads on Wafer 2 and a metal-metal conductive bond is made by applying pressure and temperature less than about 450 C.

In a fourth exemplary embodiment, Wafer 1 has an electrode passing through a through-wafer via and an electrically conductive interface, formed from a metal such as gold or platinum, in contact with an exposed portion of the electrode on the back side of the wafer. Wafer 2 includes an electrically conductive interface, also formed from gold or platinum. The electrically conductive interfaces are conductively bonded at a temperature of approximately 500 C.

In a fifth exemplary embodiment, Wafer 1 has an electrode passing through a through-wafer via and an electrically conductive interface, formed from aluminum-copper (possibly with an adhesive underlayer of titanium-tungsten, titanium, or other material), in contact with an exposed portion of the electrode on the back side of the wafer. Wafer 2 includes an electrically conductive interface, also formed from aluminum-copper (possibly with an adhesive underlayer of titanium-tungsten, titanium, or other material). The electrically conductive interfaces are conductively bonded at a temperature of approximately 450 C-500 C.

In a sixth exemplary embodiment, Wafer 1 has an electrode passing through a through-wafer via and an electrically conductive interface, formed from platinum with an underlayer of titanium-tungsten (TiW), in contact with an exposed portion of the electrode on the back side of the wafer. Wafer 2 includes an electrically conductive interface, also formed from platinum with an underlayer of titanium-tungsten. The electrically conductive interfaces are conductively bonded at a temperature of approximately 450 C.

In a seventh exemplary embodiment, Wafer 1 has an electrode passing through a through-wafer via and an electrically conductive interface, formed from platinum (possibly with an adhesive underlayer of titanium-tungsten, titanium, or other material), in contact with an exposed portion of the electrode on the back side of the wafer. Wafer 2 includes an electrically conductive interface formed from silicon or polysilicon. The electrically conductive interfaces are conductively bonded at a temperature of approximately 450 C.

The exemplary embodiments discussed above demonstrate some possible combinations of materials, process temperatures, and process pressures for conductively bonding wafer devices. It should be apparent to a skilled artisan that other materials and process temperatures may also be used. For example, it may be possible to conductively bond materials at lower temperatures, particularly if the conductive bonding is performed at higher pressures and/or in a vacuum. Conversely, it may be possible to conductively bond materials at higher temperatures.

While the exemplary embodiments discussed above demonstrate some electrically conductive interfaces composed of one or two material layers, it may be possible to have electrically conductive interfaces with more than two material layers. Extra layers may be necessary or desirable, for example, to aid in bonding.

It is well known that aluminum-copper (AlCu) generally has a native oxide. Conventional wisdom has held that this native oxide will prevent thermocompression bonding of aluminum to aluminum or AlCu to AlCu. However, AlCu to AlCu bonds were successfully formed in bonding tests at a temperature 450 C to 500 C and a bond pressure of 2-6 Bar or higher, both in an ambient and in a vacuum. In fact, leaving the as-deposited AlCu surface untreated appeared to produce a better result than if the AlCu surface was chemically or physically treated prior to bonding, although this could be due in part to constraints of the particular test procedure (e.g., the time between treatment and bonding).

It is also well known that aluminum-copper can have different proportions of aluminum and copper. Aluminum-copper with approximately one percent copper has been used successfully in bonding tests, although other percentages may also provide sufficient bonding.

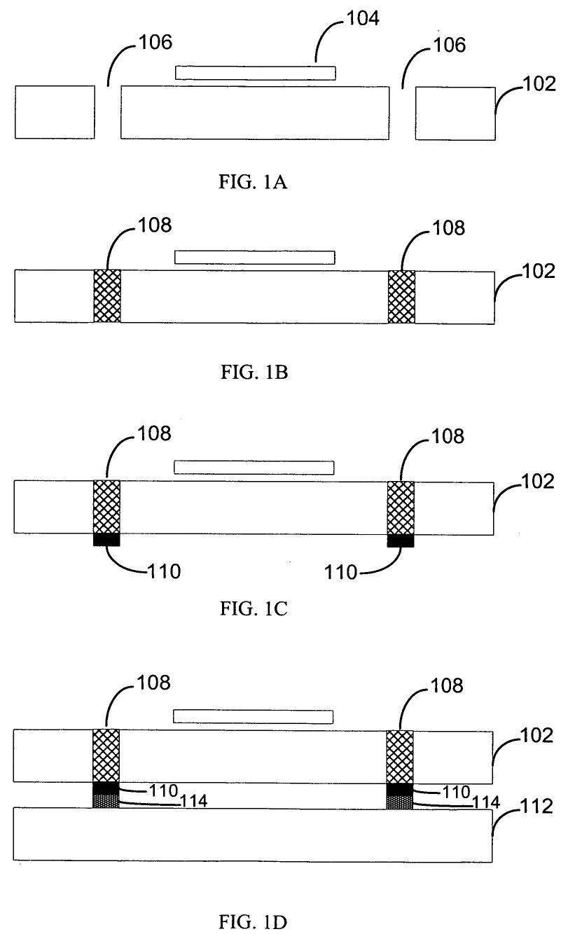

FIGS. 1A-1D show one example of a stacked die device in accordance with an embodiment of the present invention. In FIG. 1A, a first wafer 102 includes a front side component 104 and through-wafer vias 106. In FIG. 1B, the through-wafer vias 106 are filled with an electrically conductive material to form electrodes 108. The vias 106 are typically lined. In FIG. 1C, first electrically conductive interfaces, for example, in the form of a gold, platinum, or aluminum-copper pad 110, are formed on the exposed bottom of the electrodes 108. In FIG. 1D, a second wafer 112 includes second electrically conductive interfaces, for example, in the form of gold, platinum, or aluminum-copper pads 114. The pads 110 are conductively bonded to the pads 114 at a temperature of approximately 450 C-500 C, for example, at a pressure of 2-6 Bar or more, with or without vacuum.

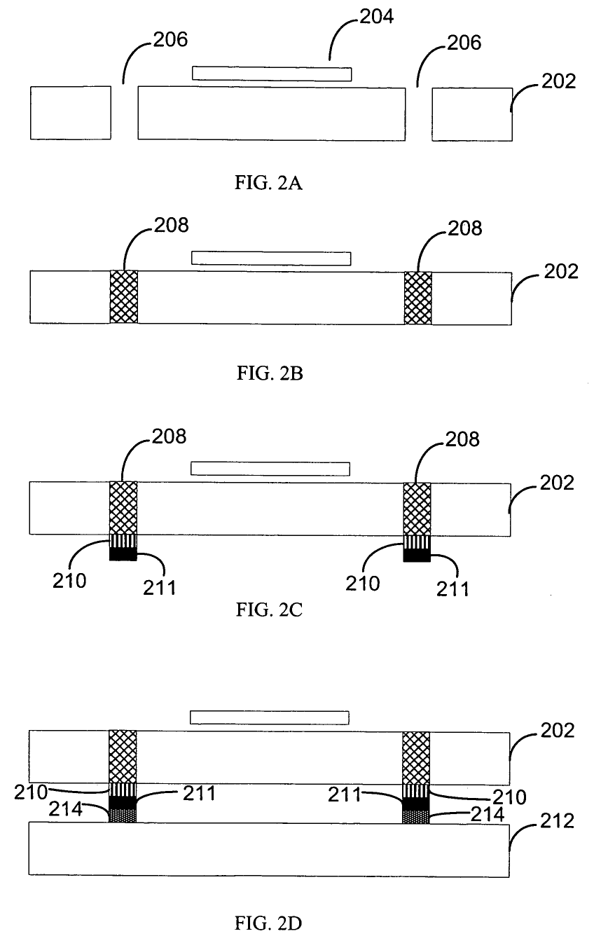

FIGS. 2A-2D show another example of a stacked die device in accordance with an embodiment of the present invention. In FIG. 2A, a first wafer 202 includes a front side component 204 and through-wafer vias 206. In FIG. 2B, the through-wafer vias 206 are filled with an electrically conductive material to form electrodes 208. The vias 206 are typically lined. In FIG. 2C, first electrically conductive interfaces, for example, in the form of a titanium-tungsten underlayer 210 and a platinum pad 211, are formed on the exposed bottom of the electrodes 208. In FIG. 2D, a second wafer 212 includes second electrically conductive interfaces, for example, in the form of a silicon pad 214. The pads 211 are conductively bonded to the pads 214 at a temperature of approximately 450 C, for example, at a pressure above 2 Bar, with or without a vacuum.

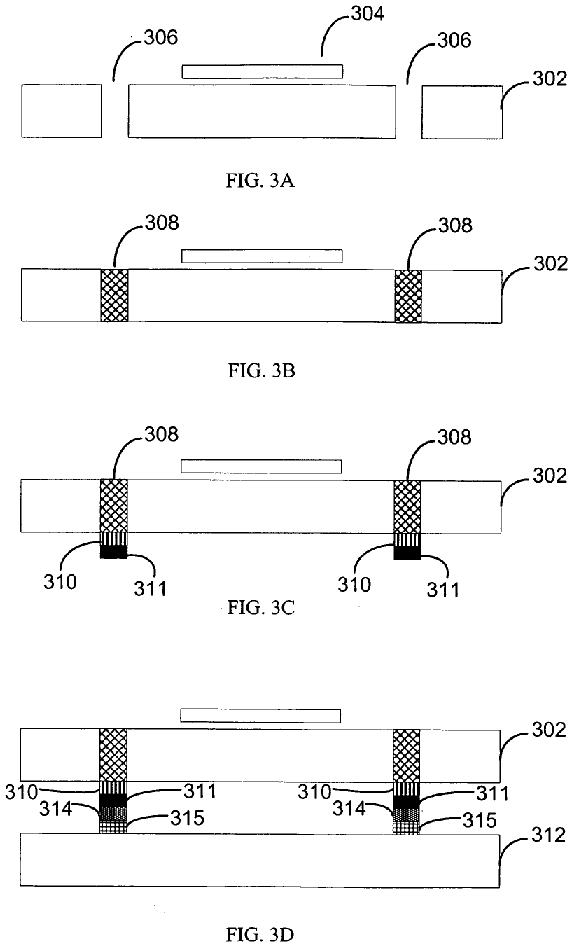

FIGS. 3A-3D show another example of a stacked die device in accordance with an embodiment of the present invention. In FIG. 3A, a first wafer 302 includes a front side component 304 and through-wafer vias 306. In FIG. 3B, the through-wafer vias 306 are filled with an electrically conductive material to form electrodes 308. The vias 306 are typically lined. In FIG. 3C, first electrically conductive interfaces, for example, in the form of a titanium-tungsten underlayer 310 and an aluminum-copper pad 311, are formed on the exposed bottom of the electrodes 308. In FIG. 3D, a second wafer 312 includes second electrically conductive interfaces, for example, in the form of a titanium-tungsten underlayer 315 and an aluminum-copper pad 314. The pads 311 are conductively bonded to the pads 314 at a temperature of approximately 450 C-500 C, for example, at a pressure above 2 Bar, with or without a vacuum.

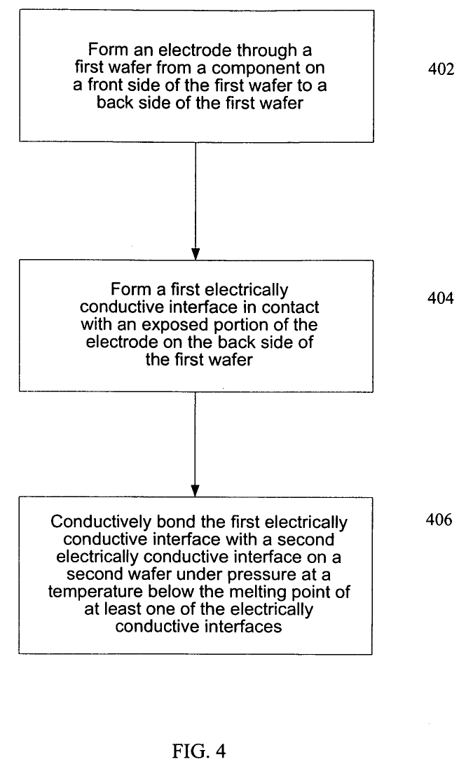

FIG. 4 is a logic flow diagram for conductively bonding wafers in accordance with an embodiment of the present invention. In block 402, an electrode is formed through a first wafer from a component on a front side of the first wafer to a back side of the first wafer. In block 404, a first electrically conductive interface is formed in contact with an exposed portion of the electrode on the back side of the first wafer. In block 406, the first electrically conductive interface is conductively bonded with a second electrically conductive interface on a second wafer under pressure at a temperature below the melting points of the electrically conductive interfaces.

To improve device performance, the electrical resistance and parasitic capacitance of the interconnects formed by the conductively filled via should be minimized. To that end, embodiments identify materials and processing steps that produce a low resistance via fill, thus enabling a good electrical connection with a via dimensioned to minimize parasitic capacitance. For example, process steps may fill the lined through-wafer via with a conductive material, such as doped polysilicon, deposited metal, or chemical vapor deposition (CVD) metal (e.g., tungsten or platinum). Related U.S. patent application Ser. No. 10/827,680 entitled “MEMS DEVICE WITH CONDUCTIVE PATH THROUGH SUBSTRATE,” which was incorporated by reference above, describes a number of techniques for forming filled through-wafer vias, including filling an etched through-wafer via and backgrinding a filled cavity. The present invention is not limited to any particular technique for forming the through-wafer via.

It should be noted that the specific temperatures recited above are exemplary for specific embodiments of the invention. Those skilled in the art should understand that other temperatures can be used to accomplish similar goals for different devices. Those skilled in the art should also recognize that electrical interconnections, formed as described above, can also act as mechanical interconnections for the wafers.

Although the above discussion discloses various exemplary embodiments of the invention, it should be apparent that those skilled in the art can make various modifications that will achieve some of the advantages of the invention without departing from the true scope of the invention.

1. A method for electrically interconnecting wafer devices, the method comprising:
forming an electrode through a first wafer from a component on a front side of the first wafer to a back side of the first wafer;
forming a first electrically conductive interface in contact with an exposed portion of the electrode on the back side of the first wafer; and
conductively bonding the first electrically conductive interface with a second electrically conductive interface on a second wafer under pressure at a temperature below the melting points of at least one of the electrically conductive interfaces.

2. A method according to claim 1, wherein conductively bonding the first electrically conductive interface with the second electrically conductive interface is performed in a vacuum.

3. A method according to claim 1, wherein the first and second electrically conductive interfaces are conductively bonded through interdiffusion.

4. A method according to claim 1, wherein the first and second electrically conductive interfaces are conductively bonded through thermocompression.

5. A method according to claim 1, wherein the first and second interfaces include gold (Au).

6. A method according to claim 1, wherein the first and second interfaces include aluminum-copper (AlCu).

7. A method according to claim 1, wherein the first and second interfaces include platinum (Pt).

8. A method according to claim 1, wherein one of the interfaces includes silicon or polysilicon and the other includes platinum (Pt).

9. A method according to claim 1, wherein one of the interfaces includes doped polysilicon and the other includes a solderable metal.

10. A method according to claim 1, wherein forming the electrode comprises:
filling a lined through-wafer via in the first wafer with an electrically conductive material.

11. A method according to claim 1, wherein the first wafer is a MEMS wafer, and wherein the second wafer is an integrated circuit wafer.

12. Apparatus comprising:
a first wafer having (1) an electrode passing through the first wafer from a component on a top side to a bottom side, and (2) a first electrically conductive interface on the bottom side of the first wafer in contact with an exposed portion of the electrode; and
a second wafer having a second electrically conductive interface conductively bonded with the first electrically conductive interface under pressure at a temperature below the melting points of at least one of the electrically conductive interfaces.

13. Apparatus according to claim 12, wherein the first and second electrically conductive interfaces are conductively bonded through interdiffusion.

14. Apparatus according to claim 12, wherein the first and second electrically conductive interfaces are conductively bonded through thermocompression.

15. Apparatus according to claim 12, wherein the first and second interfaces include gold (Au).

16. Apparatus according to claim 12, wherein the first and second interfaces include aluminum-copper (AlCu).

17. Apparatus according to claim 12, wherein the first and second interfaces include platinum (Pt).

18. Apparatus according to claim 12, wherein one of the interfaces includes silicon or polysilicon and the other includes platinum (Pt).

19. Apparatus according to claim 12, wherein one of the interfaces includes doped polysilicon and the other includes a solderable metal.

20. Apparatus according to claim 12, wherein the first wafer is a MEMS wafer and the second wafer is an integrated circuit wafer.
